(19) United States
(12) Patent Application Publication
(10) Pub. No.: US 2020/0294896 A1
(43) Pub. Date: Sep. 17, 2020

(54) Lead Frame Stabilizer for Improved Lead Planarity

(71) Applicant: Infineon Technologies AG, Neubiberg (DE)

(72) Inventors: Arivindran Navaretnasinggam, Melaka Batu Berendam (MY); Xavier Arokiasamy, Teluk Intan (MY); Thomas Bemmerl, Schwandorf (DE); Ke Yan Tean, Melaka (MY)

(21) Appl. No.: 16/351,211

(22) Filed: Mar. 12, 2019

(51) Int. Cl. H01L 23/495; H01L 23/31; H01L 21/48; H01L 23/00

(52) U.S. Cl. CPC H01L 23/49517; H01L 23/3107; H01L 23/49503; H01L 2224/48245; H01L 21/4825; H01L 21/4828; H01L 24/48; H01L 23/49541

(57) ABSTRACT

A packaged semiconductor device includes a die paddle, a semiconductor die mounted on the die paddle, a plurality of fused leads extending away from a first side of the die paddle, a discrete lead that extends away from the first side of the die paddle and is physically detached from the plurality of fused leads, a first electrical connection between a first terminal of the semiconductor die and the discrete lead, an encapsulation material that encapsulates the semiconductor die, and a stabilizer bar connected to a first outer edge side of the discrete lead. The first outer edge side of the discrete lead is opposite from a second outer edge side of the discrete lead which faces the plurality of fused leads.

### BACKGROUND

Semiconductor dies are commonly packaged with a lead frame in a molded semiconductor package. According to this technique, a lead frame structure is provided with a central die paddle and several elongated leads that extend towards the die paddle. The leads and the die paddle are typically physically supported by a peripheral ring-like structure. One or more semiconductor dies are mounted on the die paddle and electrically connected to the individual leads of the lead frame, e.g., using conductive bond wires, metal clips, etc. An electrically insulating mold compound, e.g., plastic, ceramic, etc., is formed around the semiconductor die and associated electrical connections. As a result, an insulative mold body is provided. The mold body protects the semiconductor die and electrical connections from damaging environmental conditions, such as moisture, foreign particles, etc. After the mold body is formed, the leads and the die paddle are detached from the peripheral ring, e.g., by mechanical cutting. Exposed outer ends of the leads provide externally accessible terminals for the package device that are configured to interface with another device, such as a printed circuit board.

Molded semiconductor packages can be configured according to a variety of different standardized package types. These package types differ in some structural aspect, e.g., lead configuration, mold configuration, etc. One example of a specific package type is a so-called flat no-lead package. This package type is characterized by leads that are coplanar with the molded encapsulant material at the bottom side of the package. This configuration provides so-called surface mount capability wherein the package can be directly placed on and simultaneously electrically connected with a printed circuit board.

One problem that arises in the fabrication of flat no-lead packages is the issue of mold flashing. Mold flashing refers to unwanted portions of the mold compound that partially cover the leads after the molding process is complete. This mold compound can be difficult or impossible to remove by conventional cleaning techniques. Mold flashing can determinately impact yield, as the leads may be ineffective as electrical terminals if sufficiently covered by mold compound.

### SUMMARY

A packaged semiconductor device is disclosed. According to an embodiment, the packaged semiconductor device includes a die paddle, a semiconductor die mounted on the die paddle, a plurality of fused leads extending away from a first side of the die paddle, a discrete lead that extends away from the first side of the die paddle and is physically detached from the plurality of fused leads, a first electrical connection between a first terminal of the semiconductor die and the discrete lead, an encapsulation material that encapsulates the semiconductor die, and a stabilizer bar connected to a first outer edge side of the discrete lead. The first outer edge side of the discrete lead is opposite from a second outer edge side of the discrete lead which faces the plurality of fused leads.

A lead frame is disclosed. According to an embodiment, the lead frame includes a die paddle, a semiconductor die mounted on the die paddle, a plurality of fused leads extending away from a first side of the die paddle, a discrete lead that extends away from the first side of the die paddle and is physically detached from the plurality of fused leads, a first electrical connection between a first terminal of the semiconductor die and the discrete lead, an encapsulation material that encapsulates the semiconductor die, and a stabilizer bar connected to a first outer edge side of the discrete lead. The first outer edge side of the discrete lead is opposite from a second outer edge side of the discrete lead which faces the plurality of fused leads.

A method of manufacturing a lead frame is disclosed. According to an embodiment, the method includes providing a planar sheet metal, and structuring the planar sheet metal to include a peripheral structure, a die paddle connected to the peripheral structure and comprising a first edge side that faces and is spaced apart from a first edge side of the peripheral structure, a plurality of fused leads that are each connected to the first edge side of the peripheral structure and are each fused together by a fuse connector at a location that is between the first edge side of the peripheral structure and the die paddle, a discrete lead that is connected to the first edge side of the peripheral structure, and is separated from the fuse connector, and a stabilizer bar that is connected between the peripheral structure and an outer edge side of the discrete lead.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a lead frame with a stabilizer bar, according to an embodiment.

FIG. 2 illustrates a lead frame with a stabilizer bar, according to another embodiment.

FIG. 3, which includes FIGS. 3A and 3B, illustrates cross-sectional views of specific regions of a lead frame with a stabilizer bar, according to an embodiment.

FIG. 4 illustrates forming a packaged semiconductor device on a lead frame with a stabilizer bar, according to another embodiment.

FIG. 5, which includes FIGS. 5A and 5B, illustrates a packaged semiconductor device formed from a lead frame with a stabilizer bar, according to an embodiment. FIG. 5A shows a lower side of the packaged semiconductor device from a plan-view perspective. FIG. 5B illustrates a side view of the packaged semiconductor device.

FIG. 6 illustrates the influence of a stabilizer bar on the movement of a discrete lead, according to an embodiment.

### DETAILED DESCRIPTION

According to embodiments described herein, a lead frame is provided to include a stabilizer bar that advantageously mitigates the problem of mold flashing and improves wire bond capability. In more derail, a lead frame includes a die paddle, a peripheral structure, a plurality of fused leads, and a discrete lead. The discrete lead is independent from the fused leads and, in the absence of further measures, would be prone to tilting and/or flexing during various steps for processing and handling of the lead frame. Advantageously, the lead frame additionally includes a stabilizer bar that mitigates this tilting and/or flexing of the discrete lead. The stabilizer bar is connected between an outer edge side of the discrete lead and the peripheral structure. This connection anchors the discrete lead at a second location before and during the encapsulation process. Consequently, the lower surface of the discrete lead is more closely aligned with the lower surface of the die paddle and the fused leads at the lower side of the completed packaged device. This mitigates so-called mold flashing wherein liquified mold compound accumulates on the discrete lead as a result of the non-planarity of the discrete lead. Additionally, this improves wire bond capability by providing a more stable surface that is less prone to movement (e.g., from bouncing of the discrete lead) during the wire bond process.

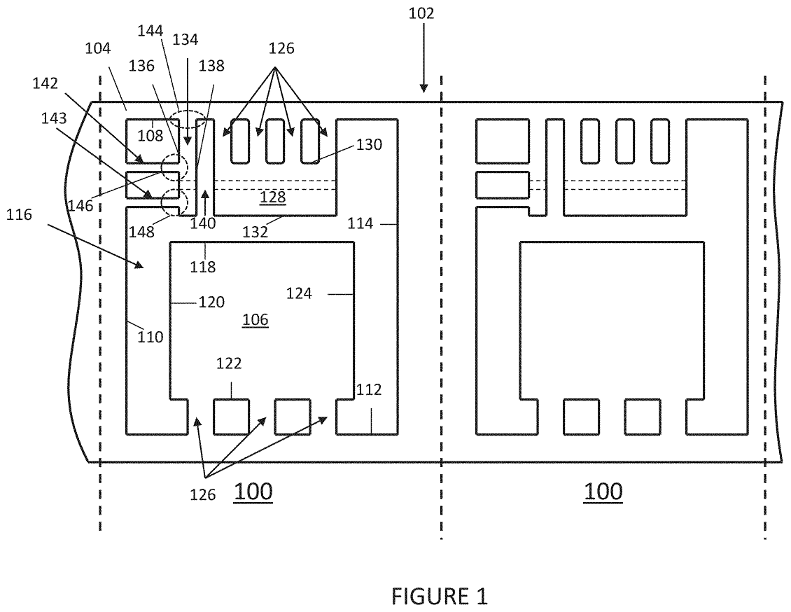

Referring to FIG. 1, a lead frame 100 that is used to form a packaged semiconductor device is depicted, according to an embodiment. The lead frame 100 is provided from a lead frame strip 102 that includes a plurality of identically configured unit lead frames 100, two of which are depicted in FIG. 1.

The lead frame 100 includes a peripheral structure 104. The peripheral structure 104 is an outside portion of the lead frame 100 that does not form part of the completed package device. Instead, the peripheral structure 104 is used mechanically support the features of the lead frame 100 during processing. In the depicted embodiment, the peripheral structure 104 forms a loop around a centrally located die paddle 106. In the depicted embodiment, the peripheral structure 104 includes first, second, third, and fourth edge sides 108, 110, 112, and 114 that surround a central opening 116. These edge sides 108, 110, 112, and 114 form an angled intersection with one another. That is, these edge sides 108, 110, 112, and 114 form oblique angles with one another. In the depicted embodiment, each of the first, second, third, and fourth edge sides 108, 110, 112, and 114 form ninety-degree angles with one another such that the central opening 116 has a general shape of a rectangle. More generally, the peripheral structure 104 can be configured in a variety of different geometries, and the inner edge sides of the peripheral structure 104 can include non-perpendicular angles and/or curved geometries.

The lead frame 100 includes a die paddle 106 that is disposed within the central opening 116 of the peripheral structure 104. As depicted, the die paddle 106 has a generally rectangular shape, with first, second, third and fourth edge sides 118, 120, 122, and 124 that respectively face the first, second, third and fourth edge sides 108, 110, 112, and 114 of the peripheral structure 104. More generally, the die paddle 106 can have a variety of geometries. The die paddle 106 is physically connected to the peripheral structure 104 and hence mechanically supported by the peripheral structure 104. In the depicted embodiment, this physical connection is provided by a number of tie bars 126 extending between the third edge side 122 of the die paddle 106 and the third edge side 112 of the peripheral structure 104. Additionally, or alternatively, one or more leads (not shown) may be connected between the die paddle 106 and the peripheral structure 104.

The lead frame 100 includes several leads that face the first edge side 118 of the die paddle 106. Each of these leads are connected to the first edge side 108 of the peripheral structure 104. In more detail, each of these leads include opposite facing outer edge sides that intersect and merge with the peripheral structure 104 at the first edge side 108 of the peripheral structure 104. This location of the leads will be referred to as the distal end of the leads in the following description. Each of these leads include ends opposite from the distal ends that face the first edge side of the die pad. This location of the leads will be referred to as the proximal ends of the leads in the following description. According to an embodiment, the proximal end of each lead is spaced apart from the first edge side 118 of the die paddle 106. Alternatively, one or more leads may extend completely from the first edge side 108 of the peripheral structure 104 to the first edge side 118 of the die paddle 106.

Included in the leads that face the first edge side 118 of the die paddle 106 is a plurality (i.e., two or more) of fused leads 126. The fused leads 126 are fused together by a fuse connector 128. The fuse connector 128 is disposed at a location that is between the first edge side 108 of the peripheral structure 104 and the first edge side 118 of die paddle 106. This means that the fuse connector 128 is closer to the first edge side 118 of the die paddle 106 than the distal ends of the fused leads 126. The fuse connector 128 can be provided from a continuous metal pad that includes an inner edge side 130 and an outer edge side 132. The inner edge side 130 of the fuse connector 128 extends transversely across outer edge sides of the fused leads 126. The outer edge side 132 of the fuse connector 128 faces and is spaced apart from the die paddle 106. In the depicted embodiment, the outer edge side 132 of the fuse connector 128 is coextensive with the proximal ends of the fused leads 126. In other embodiments, the outer edge side 132 can be located between the distal and proximal ends of the fused leads 126 such that the fused leads 126 regain the shape of individual leads as they approach the first edge side 118 of the die paddle 106.

Also included in the leads that face the first edge side 118 of the die paddle 106 is a discrete lead 134. The discrete lead 134 is separated from the fuse connector 128. This means that the outer edge sides of the discrete lead 134 do not contact the fuse connector 128. Put another way the discrete lead 134 is separate and independent from the fused leads 126 except for the connections to the peripheral structure 104, which are eventually severed in the completed device.

The discrete lead 134 includes first and second opposite facing outer edge sides 136, 138 that each connect to the first edge side 108 of the peripheral structure 104. The first outer edge side 136 of the discrete lead 134 faces the second edge side 110 of the peripheral structure 104. The second outer edge side 138 of the discrete lead 134 faces the plurality of fused leads 126. According to an embodiment, the discrete lead 134 is an outermost lead of all of the leads that are connected to the first edge side 108 of the peripheral structure 104. This means that no other leads are disposed between the discrete lead 134 and the peripheral structure 104 in a lateral direction of the leads, i.e., a direction that is perpendicular to the outer edge sides of the leads.

According to an embodiment, a gap 140 that spans a complete length of the discrete lead 134 is provided between the second outer edge side 138 of the discrete lead 134 and the plurality of fused leads 126. In this context, the complete length of the discrete lead 134 refers to a length of the discrete lead 134 from the distal end to the proximal end of the discrete lead 134. In this embodiment, the second outer edge side 138 of the discrete lead 134 directly faces an edge side of one of the leads from the plurality of fused leads 126. In other embodiments (not shown) additional elements, such as additional discrete leads, may be disposed between the discrete lead 134 and the fused leads 126. In any case, the second outer edge side 138 of the discrete lead 134 is physically spaced apart from the fused leads 126 due to the gap 140. Moreover, because of the gap 140, the discrete lead 134 forms a separate electrical node as the fused leads 126 in the completed device.

The lead frame 100 additionally includes a first stabilizer bar 142. The first stabilizer bar 142 is connected between the peripheral structure 104 and an outer edge side of the discrete lead 134. According to an embodiment, the first stabilizer bar 142 extends transversely away from one of the outer edge sides of the discrete lead 134. This means that the first stabilizer bar 142 forms an angled intersection with an outer edge side of the discrete lead 134. For example, as shown, the first stabilizer bar 142 may include opposite facing outer edge sides that join and form a substantially perpendicular angle with the first outer edge side 136 of the discrete lead 134. More generally, the first stabilizer bar 142 can be disposed at any oblique angle relative to an edge side of the discrete lead 134. According to an embodiment, first stabilizer bar 142 is disposed on a side of the discrete lead 134 that does not face any leads. For example, in the depicted embodiment wherein the discrete lead 134 is an outermost lead, the first stabilizer bar 142 is provided in a region of the opening 116 that is between the first outer edge side 136 of the discrete lead 134 and the second outer edge side 110 of the peripheral structure 104. In this example, the first stabilizer bar 142 extends directly between the second edge side 110 of the peripheral structure 104 and the first edge side of the discrete lead 134. As previously explained, the geometry of the peripheral structure 104 may vary from what is shown in different lead frame 100 configurations. In any case, the geometry of the first stabilizer bar 142 can be adapted so that the first stabilizer bar 142 proves a direct connection between an outer edge side of the discrete lead 134 and an edge side of the peripheral structure 104. For example, the first stabilizer bar 142 can include angled or curved geometries to complete this direct connection.

As a result of the first stabilizer bar 142, the discrete lead 134 is physically coupled to the peripheral structure 104 at two locations. Specifically, the first stabilizer bar 142 connects directly to the peripheral structure 104 at a first location 144. The first location 144 is the intersection between the first and second outer edge 136, 138 sides of the discrete lead 134 and the first edge side 108 of the peripheral structure 104, i.e., the distal end of the discrete lead 134. Additionally, the discrete lead 134 is physically coupled to the peripheral structure 104 at a second location 146. The second location 146 is at an intersection between edge sides of the first stabilizer bar 142 and an outer edge side of the discrete lead 134. The second location 146 is closer to the die paddle 106 than the first location 144. This means that the connection between the first stabilizer bar 142 and the discrete lead 134 is closer to the proximal end of the discrete lead 134 than the first location 144. In the depicted embodiment, the second location 146 is about halfway between the distal and proximal ends of the discrete lead 134. More generally, the second location 146 can be disposed at any location that is spaced apart from the distal end of the discrete lead 134, including a location that is at or near the proximal end of the discrete lead 134.

According to an embodiment, the lead frame 100 includes a second stabilizer bar 143 connected between the peripheral structure 104 and an outer edge side of the discrete lead 134. The second stabilizer bar 143 may be configured in a substantially similar or identical manner as the first stabilizer bar 142 according to any of the embodiments of the first stabilizer bar 142 described herein. As shown, the second stabilizer bar 143 connects to the first outer edge side 136 of the discrete lead 134 at a third location 148 that is closer to the die paddle 106 than the first and second locations 144, 146. Moreover, the second stabilizer bar 143 comprises outer edge sides that are substantially parallel to the outer edge sides of the first stabilizer bar 142 and perpendicular to the first outer edge side 136 of the discrete lead 134. More generally, the second stabilizer bar 143 can be oriented at any angle relative to the discrete lead 134 and edge sides of the peripheral structure 104 in a similar manner as previously described with reference to the first stabilizer bar 142.

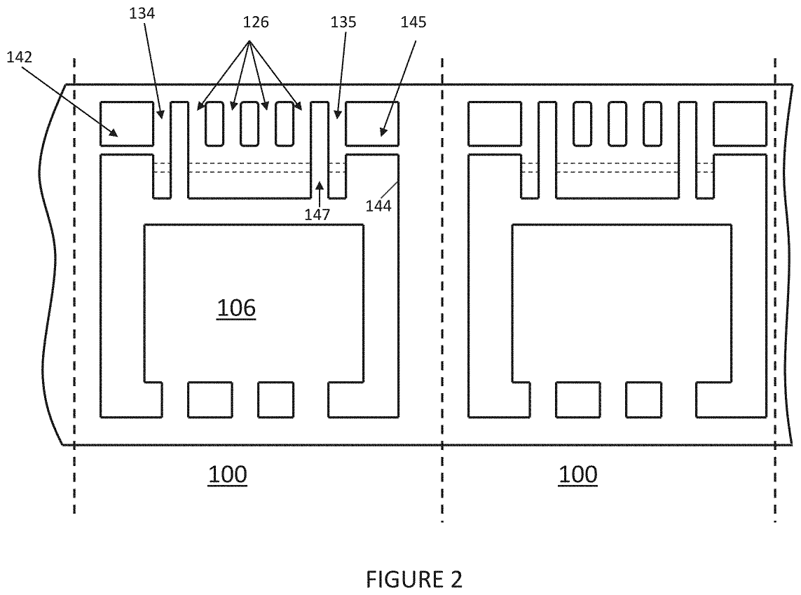

Referring to FIG. 2, a lead frame 100 that is used to form a packaged semiconductor device is depicted, according to another embodiment. The lead frame 100 of FIG. 2 is substantially identical to the lead frame 100 of FIG. 1, with the exception that this lead frame 100 additionally includes a second discrete lead 135 and a third stabilizer bar 145 connected between the second discrete lead 135 and the peripheral structure 104. In this configuration, the second discrete lead 135 is an outermost lead that is provided at the opposite lateral end of the plurality as the first discrete lead 134. An inner edge side of the second discrete lead 135 is spaced apart from the fused leads 126 by a second gap 147 that spans the length of the second discrete lead 135 in a similar manner as previously discussed. The third stabilizer bar 145 is connected between the outer edge side of the second discrete lead 135 and the third edge side 144 of the peripheral structure 104. The third stabilizer bar 145 may be configured in a substantially similar or identical manner as the first stabilizer bar 142 according to any of the embodiments of the first stabilizer bar 142 described herein.

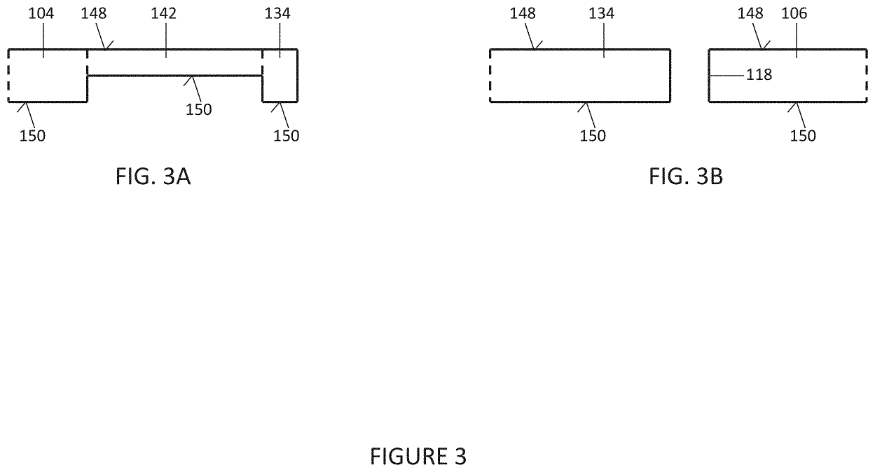

Referring to FIG. 3, various cross-sectional views of the lead frame 100 are shown. FIG. 3A depicts a view of the lead frame 100 along a cross-section that includes the peripheral structure 104, the first stabilizer bar 142 and the discrete lead 134. FIG. 3B depicts a view of the lead frame 100 along a cross-section that includes a proximal end of the first stabilizer bar 142 and the die paddle 106.

As shown in FIG. 3A, the first stabilizer bar 142 can be configured as a reduced thickness portion of the lead frame 100. That is, the first stabilizer bar 142 can be relatively thinner in comparison to other portions of the lead frame 100, e.g., the discrete lead 134, the die paddle 106, etc. In this context, the thickness of the lead frame 100 refers to the shortest distance measured between opposite facing upper and lower surfaces 148, 150 of the lead frame 100. In the example of FIG. 3A, the reduced thickness of the lead frame 100 is provided by a vertical offset of the lower surface 150 of the lead frame 100 in the region of the first stabilizer bar 142. Meanwhile, the upper surface 148 of the lead frame 100 at the first stabilizer bar 142 is substantially coplanar with the upper surface 148 of the lead frame 100 at the discrete lead 134. Thus, the reduction in thickness is provided exclusively at one side of the lead frame 100. As shown in FIG. 3B, the upper and lower surfaces 148, 150 of the lead frame 100 at the discrete lead 134 are substantially coplanar with the upper and lower surfaces 148, 150 of the lead frame 100 in the die paddle 106. Hence, the above described vertical offset of the lower surface 150 at the first stabilizer bar 142 means that a bottom side of the first stabilizer bar 142 is offset from bottom sides of the leads and the die paddle 106.

The lead frame 100 as described herein can be formed by the following technique. Initially, a sheet layer of electrically conductive material (e.g., copper, aluminum, alloys thereof, etc., is provided). Subsequently, openings are formed in the sheet layer which define the edge sides of the various geometric features, e.g., the leads, the die paddle 106, the first stabilizer bar 14, etc. These openings can be formed according to a variety of different techniques, such as etching, stamping, punching, etc. In addition, or in the alternative, structures can be attached to the lead frame 100 using techniques such as soldering, riveting, etc., to provide at least some of the various geometric features of the lead frame 100 described herein.

According to an embodiment, the reduced thickness geometry of the first stabilizer bar 142 as described with reference to FIG. 3A is formed using a half-etch technique. Half-etching refers to a technique whereby the etching is controlled, e.g., through appropriate use of mask geometry, time, etchant chemical, etc., to prevent the etchant from completely penetrating the material. In one example of this technique, two masks are provided on both sides of a planar sheet metal. These masks are patterned as mirror images of one another, except that the half-etched features are only structured on one side of the two masks. The etching process is carried to remove about half of the thickness of the sheet metal such that complete openings form in the regions exposed by both masks, and half depth recesses form in the regions that are only exposed by one mask, i.e., the half-etched regions.

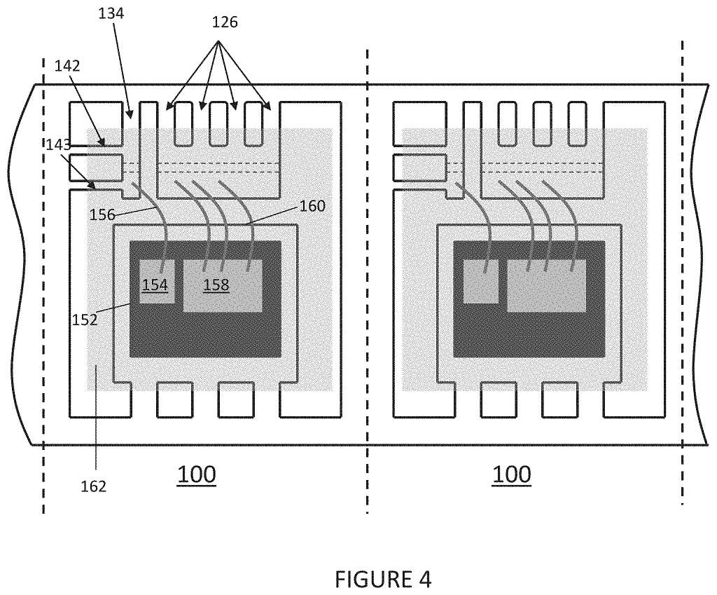

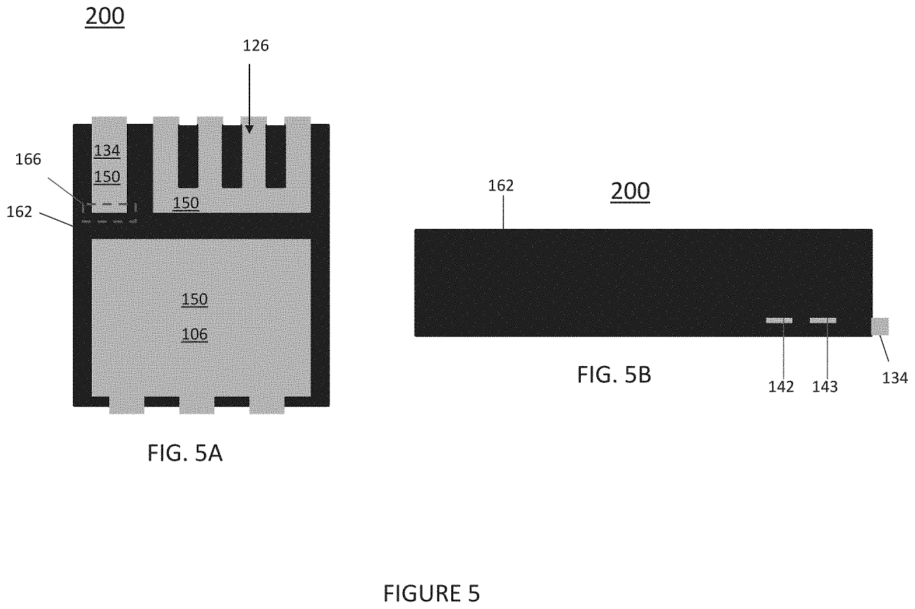

Referring to FIG. 4, the lead frame 100 as described with reference to FIG. 1 can be used to form a packaged semiconductor device 200 (shown in FIG. 5) according to the following technique. Once the lead frame 100 is provided, the lead frame 100 can placed on a temporary carrier (not shown) that is suitable for handling and transfer of electronic components through various semiconductor processing tools. A semiconductor die 152 is mounted on the upper surface 148 of the lead frame 100 at the die paddle 106. This can be done by providing an adhesive, e.g., solder, sinter, tape, etc., between the lower side of the semiconductor die 152 and the die paddle 106. Subsequently, electrical connections are provided between the terminals of the semiconductor die 152 and the various leads of the lead frame 100. Generally speaking, these electrical connections can be provided according to any conventionally known technique, such as bond wires, clips, ribbon, etc. In the depicted embodiment, the semiconductor die 152 includes a first terminal 154 that is electrically connected to the discrete lead 134 by a single bond wire 156, and a second terminal 158 that is electrically connected to the fused leads 126 by a plurality of bond wires 160.

According to an embodiment, the semiconductor die 152 is configured as a power device, i.e., a device that is configured to block large voltages, e.g., 200 volts or more, and/or accommodate large currents, e.g., 1 ampere or more. For example, the semiconductor die 152 can be configured as a power transistor, such as a MOSFET (Metal Oxide Semiconductor Field Effect Transistors) or Insulated Gate Bipolar Transistor (IGBT) wherein the first terminal 154 is a gate terminal and the second terminal 158 is a drain terminal of the device. In that case, the source terminal can be provided on the lower side of the semiconductor die 152, and the die paddle 106 provides a corresponding source connection for the semiconductor die 152.

More generally, the semiconductor die 152 can have any of a wide variety of device configurations. These device configurations include discrete devices such as HENT (high electron mobility transistor) devices, diodes, thyristors, etc. These device configurations also include integrated devices such as, controllers, amplifiers, etc. These device configurations include vertical device configurations, i.e., devices which conduct in a direction perpendicular to the upper and lower surfaces of the die, and lateral device configurations, i.e., devices which conduct in a direction parallel to the upper and lower surfaces of the die. In any case, the discrete lead 134 and the fused leads 126 can be separately electrically connected to different terminals of the semiconductor die 152. Without necessarily being limited thereto, the fused leads 126 are generally preferable for large current carrying terminals, e.g., source, drain, etc. By contrast, the discrete leads 134 are generally preferable for smaller current carrying terminals, e.g., gate, sensor, etc.

After electrically connecting the semiconductor die 152 to the lead frame 100, the semiconductor die 152 is encapsulated with an electrically insulating mold compound 162. The mold compound 162 is shown as translucent in FIG. 4 so that the encapsulated components are visible in the figure. However, in practice, this material is typically opaque. The mold compound 162 can include a wide variety of electrically insulating materials such as ceramics, epoxy materials and thermosetting plastics, to name a few. The mold compound 162 can be formed using any of a variety of known techniques, such as injection molding, transfer molding, compression molding, etc. The mold compound 162 is formed to completely encapsulate, i.e., cover and surround, the semiconductor die 152 and associated electrical connections, which in the depicted embodiment are provided by the bond wires 156 and 160. In an embodiment, the mold compound 162 can be formed to expose the distal ends of each of the leads, e.g., as shown. After the mold compound 162 is formed and hardened, each of the leads can be separated from the peripheral structure 104, e.g., by a mechanical cutting process.

Referring to FIG. 5, a completed packaged semiconductor device 200 is shown after separation from the peripheral structure 104 of the lead frame 100, according to an embodiment. As shown in FIG. 5A, the lower surface 150 of the lead frame 100 in the die paddle 106 and lead regions is exposed at the bottom side of the packaged device. According to an embodiment, the exposed portions of the lower surface 150 of the lead frame 100 are coplanar with the lower surface of the mold compound 162. As a result, the die paddle 106 and leads provide so-called surface mount capability that allow the packaged semiconductor device 200 to interface with a corresponding device, e.g., a PCB socket. Various planarization and or cleaning techniques can be performed so that the metal portions of the lead frame 100 are clearly exposed from the mold compound 162 and provide a clean surface connection.

As shown in FIG. 5B, the first and second stabilizer bars 142 and 143 extend to an outer side surface of the mold compound 162 body. In the depicted embodiment, ends of the first and second stabilizer bars 142 and 143 are exposed from the mold compound 162. In general, these ends can be disregarded as functional features, as the discrete lead 134 provides electrical access to the same terminal. However, if desired, an additional molding step can be performed to cover the exposed ends of the first and second stabilizer bars 142 and 143.

As can be seen, the first and second stabilizer bars 142 and 143 are covered on both sides by the mold compound 162. This configuration can be made possible by forming the stabilizer bars 142 and 143 with the reduced thickness geometry as described with reference to FIG. 3A. By vertically offsetting the lower surface 150 of the lead frame 100 as previously described, the encapsulation process completely covers the lower surface 150 of the lead frame 100 at the first and second stabilizer bars 142 and 143 with the mold compound 162. Hence, as shown in FIG. 5A, the first and second stabilizer bars 142 and 143 are not exposed at the lower side of the packaged device. Thus, the first and second stabilizer bars 142 and 143 do not alter the surface mount footprint of the device.

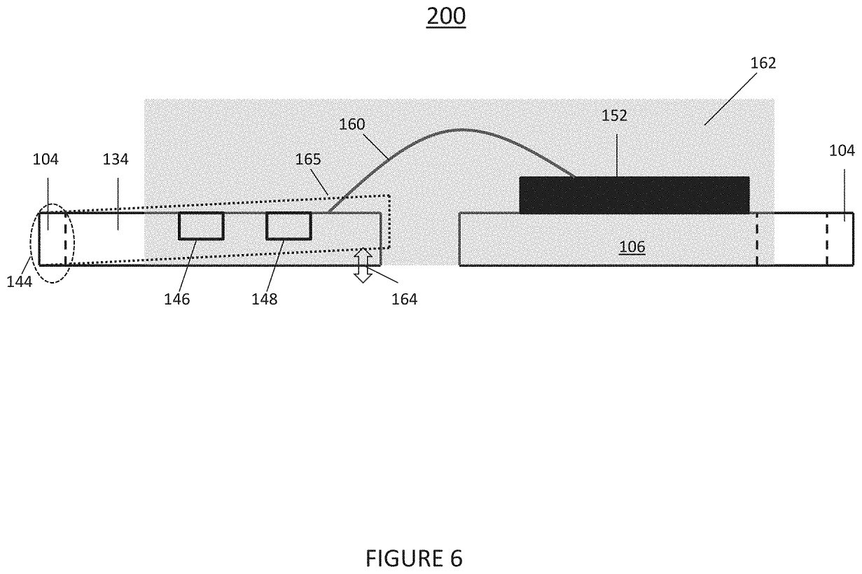

Referring to FIG. 6, potential range of movement 164 for a hypothetical discrete lead 165 that is not connected to the peripheral structure 104 is shown. This range of movement 164 illustrates a tilting and/or flexing of the hypothetical discrete lead 165 wherein the hypothetical discrete lead 165 deviates from the plane of the die paddle 106. This movement can be caused by forces applied to the discrete lead 134 during various processing steps for forming the packaged device. For example, this movement can arise from mechanical forces applied to the lead frame 100 during handling of the lead frame 100. Alternatively, this movement may arise from compressive or tensile stresses that arise in the packaged device 200 during high temperature processing steps, wherein materials with different coefficients of thermal expansion expand or contract at different rates. As can be seen, the first connection point 144 between the discrete lead 134 and the peripheral structure 104 acts as a fulcrum such that the proximal end of the discrete lead 134 has significant leverage. Thus, significant rotational movement of the discrete lead 134 is possible with low amounts of force. By way of comparison, the fused leads 126 as described herein are less prone to this kind of movement due to the added mechanical strength provided by the fuse connector 128. Moreover, the fused leads 126 move independently from the discrete lead 134. Thus, in the absence of an anchor mechanism, the discrete lead 134 can become tilted relative to the fused leads 126 due to the above described phenomena.

Because the first and second stabilizer bars 142, 143 physically couple the discrete lead 134 to the peripheral structure 104 at the second and third locations 146, 148, there is less leverage at the proximal end of the discrete lead 134. Hence, the above described mechanical forces applied to the lead frame 100 are less effective at tilting or flexing the discrete lead 134. Hence, the discrete lead 134 remains aligned at or close to the plane of the die paddle 106 throughout the encapsulating of the semiconductor die 152. Once the mold compound 162 is hardened, the position of the discrete lead 134 is fixed and the first and second stabilizer bars 142, 143 can be detached.

Referring again to FIG. 5, an area 166 of the packaged device is shown that is susceptible to mold flashing if the discrete lead 134 is permitted to move by the potential range of movement 164 as shown in FIG. 6. If the discrete lead 134 is sufficiently tilted relative to the die paddle 106 and/or the fused leads 126, this area 106 becomes covered with mold compound 162 in the completed device. Hence, the first stabilizer bar 142 advantageously avoids this outcome by preventing the discrete lead 134 from tilting in this way.

While FIG. 6 illustrates an embodiment that includes both the first and second stabilizer bars 142, 143, a beneficial impact on rotational movement and/or reduction in mold flashing as described herein can be achieved with different numbers and or configurations of stabilizers, including embodiments that include only one stabilizer bar connected to a discrete lead.

An embodiment of a packaged semiconductor device includes a die paddle, a semiconductor die mounted on the die paddle, a plurality of fused leads extending away from a first side of the die paddle, a discrete lead that extends away from the first side of the die paddle and is physically detached from the plurality of fused leads, a first electrical connection between a first terminal of the semiconductor die and the discrete lead, an encapsulation material that encapsulates the semiconductor die, and a stabilizer bar connected to a first outer edge side of the discrete lead. The first outer edge side of the discrete lead is opposite from a second outer edge side of the discrete lead which faces the plurality of fused leads.

According to an embodiment that can be combined with others, the fused leads and the discrete lead extend to a first outer sidewall of the encapsulation material, wherein the stabilizer bar extends to a second outer sidewall of the encapsulation material, and the first and second outer sidewalls of the encapsulation material are angled relative to one another.

According to an embodiment that can be combined with others, a gap that spans a complete length of the discrete lead is provided between the second outer edge side of the discrete lead and the plurality of fused leads.

According to an embodiment that can be combined with others, a thickness of the stabilizer bar is less than a thickness of the discrete lead.

According to an embodiment that can be combined with others, the stabilizer bar comprises an upper surface that is coplanar with an upper surface of the discrete lead and a lower surface that is vertically offset from a lower surface of the discrete lead, and wherein the lower surface of the stabilizer bar is covered by the encapsulation material.

According to an embodiment that can be combined with others, the packaged device further includes a second stabilizer bar connected to the first outer edge side of the discrete lead.

An embodiment of a method of forming a semiconductor device comprises providing a lead frame that comprises a peripheral structure, a die paddle connected to the peripheral structure and comprising a first edge side that faces and is spaced apart from a first edge side of the peripheral structure, a plurality of fused leads that are each connected to the first edge side of the peripheral structure and are each fused together by a fuse connector at a location that is between the first edge side of the peripheral structure and the die paddle, a discrete lead that is connected to the first edge side of the peripheral structure, and is separated from the fuse connector, and a stabilizer bar that is connected between the peripheral structure and an outer edge side of the discrete lead, mounting a semiconductor die on the die paddle, and encapsulating the semiconductor die with an electrically insulating mold compound while the stabilizer bar connected between the peripheral structure and an outer edge side of the discrete lead.

According to an embodiment that can be combined with others, the discrete lead comprises first and second opposite facing outer edge sides that each connect to the first edge side of the peripheral structure at a first location, and wherein the stabilizer bar connects to the first outer edge side of the discrete lead at a second location that is closer to the die paddle than the first location.

According to an embodiment that can be combined with others, the discrete lead comprises a proximal end that faces the die paddle, and the second location is between the first location and the proximal end of the discrete lead.

According to an embodiment that can be combined with others, the second outer edge side of the discrete lead faces the plurality of fused leads, and a gap that spans a complete length of the discrete lead is provided between the second outer edge side of the discrete lead and the plurality of fused leads.

According to an embodiment that can be combined with others, the peripheral structure comprises a second edge side that forms an angled intersection with the first edge side, and the stabilizer bar extends between the second edge side of the peripheral structure and the first outer edge side of the discrete lead.

According to an embodiment that can be combined with others, the fuse connector is a continuous metal pad that comprises an inner edge side and an outer edge side, the inner edge side of the fuse connector extends transversely across outer edge sides of the fused leads, and the outer edge side of the fuse connector faces and is spaced apart from the die paddle.

According to an embodiment that can be combined with others, the discrete lead is an outermost lead of all leads connected to the first edge side of the peripheral structure, and the stabilizer bar is disposed on a side of the discrete lead that does not face any leads.

According to an embodiment that can be combined with others, the lead frame further comprises a second stabilizer bar connected between the peripheral ring and the outer edge side of the discrete lead.

According to an embodiment that can be combined with others, the stabilizer bar is a reduced thickness portion of the lead frame.

According to an embodiment that can be combined with others, the lead frame comprises opposite facing upper and lower surfaces, the upper surface of the lead frame at the stabilizer bar is substantially coplanar with the upper surface of the lead frame at discrete lead, and the lower surface of the lead frame at the stabilizer bar is vertically offset from the lower surface of the lead frame at discrete lead.

According to an embodiment that can be combined with others, encapsulating the semiconductor die comprises completely covering the lower surface of the lead frame at the stabilizer bar.

A lead frame includes a die paddle, a semiconductor die mounted on the die paddle, a plurality of fused leads extending away from a first side of the die paddle, a discrete lead that extends away from the first side of the die paddle and is physically detached from the plurality of fused leads, a first electrical connection between a first terminal of the semiconductor die and the discrete lead, an encapsulation material that encapsulates the semiconductor die, and a stabilizer bar connected to a first outer edge side of the discrete lead. The first outer edge side of the discrete lead is opposite from a second outer edge side of the discrete lead which faces the plurality of fused leads.

According to an embodiment that can be combined with others, the discrete lead comprises first and second opposite facing outer edge sides that each connect to the first edge side of the peripheral structure at a first location, and the stabilizer bar connects to the first outer edge side of the discrete lead at a second location that is closer to the die paddle than the first location.

According to an embodiment that can be combined with others, the discrete lead comprises a proximal end that faces the die paddle, and the second location is between the first location and the proximal end of the discrete lead.

According to an embodiment that can be combined with others, the second outer edge side of the discrete lead faces the plurality of fused leads, and a gap that spans a complete length of the discrete lead is provided between the second outer edge side of the discrete lead and the plurality of fused leads.

According to an embodiment that can be combined with others, the peripheral structure comprises a second edge side that forms an angled intersection with the first edge side, and the stabilizer bar extends between the second edge side of the peripheral structure and the first outer edge side of the discrete lead.

According to an embodiment that can be combined with others, the discrete lead is an outermost lead of all leads connected to the first edge side of the peripheral structure, and the stabilizer bar is disposed on a side of the discrete lead that does not face any leads.

According to an embodiment that can be combined with others, the lead frame further comprises a second stabilizer bar connected between the peripheral ring and the outer edge side of the discrete lead.

According to an embodiment that can be combined with others, a thickness of the stabilizer bar is less than a thickness of the discrete lead.

According to an embodiment that can be combined with others, the lead frame comprises opposite facing upper and lower surfaces, the upper surface of the lead frame at the stabilizer bar is substantially coplanar with the upper surface of the lead frame at discrete lead, and the lower surface of the lead frame at the stabilizer bar is vertically offset from the lower surface of the lead frame at discrete lead.

A method of manufacturing a semiconductor device comprises providing a lead frame comprising a die paddle, a peripheral structure, a plurality of fused leads, a discrete lead, and a stabilizer bar that extends away from an outer edge side of the discrete lead, mounting a semiconductor die on the die paddle, electrically connecting a first terminal of the semiconductor die to the discrete lead, electrically connecting a second terminal of the semiconductor die to the fused leads, encapsulating the semiconductor die with an electrically insulating mold compound, and physically coupling the discrete lead to the peripheral structure via the stabilizer bar during the encapsulating of the semiconductor die.

According to an embodiment that can be combined with others, a distal end of the discrete lead is physically coupled to the peripheral structure at a first location during the encapsulating of the semiconductor die, and the discrete lead is physically coupled to the peripheral structure via the stabilizer bar at a second location that is spaced apart from the distal end of the discrete lead.

According to an embodiment that can be combined with others, the distal end of the discrete lead is physically coupled to the peripheral structure at the first location by a direct connection between opposite facing outer edge sides of the discrete lead and a first edge side of the peripheral structure, and each of the fused leads comprise distal ends that are directly connected to the first edge side of the peripheral structure.

According to an embodiment that can be combined with others, the peripheral structure comprises a second edge side that is oriented transversely relative to the first edge side of the peripheral structure, and physically coupling the discrete lead to the peripheral structure via the stabilizer bar comprises coupling the discrete lead to the second edge side of the peripheral structure.

A method of forming a lead frame comprises providing a planar sheet metal, and structuring the planar sheet metal to include a peripheral structure, a die paddle connected to the peripheral structure and comprising a first edge side that faces and is spaced apart from a first edge side of the peripheral structure, a plurality of fused leads that are each connected to the first edge side of the peripheral structure and are each fused together by a fuse connector at a location that is between the first edge side of the peripheral structure and the die paddle, a discrete lead that is connected to the first edge side of the peripheral structure, and is separated from the fuse connector, and a stabilizer bar that is connected between the peripheral structure and an outer edge side of the discrete lead.

According to an embodiment that can be combined with others, the discrete lead comprises first and second opposite facing outer edge sides that each connect to the first edge side of the peripheral structure at a first location, and wherein the stabilizer bar connects to the first outer edge side of the discrete lead at a second location that is closer to the die paddle than the first location.

According to an embodiment that can be combined with others, the second outer edge side of the discrete lead faces the plurality of fused leads, and a gap that spans a complete length of the discrete lead is provided between the second outer edge side of the discrete lead and the plurality of fused leads.

According to an embodiment that can be combined with others, structuring the planar sheet metal comprises forming the stabilizer bar to be a reduced thickness portion of the lead frame.

According to an embodiment that can be combined with others, forming the stabilizer bar to be a reduced thickness portion of the lead frame comprises performing a half-etch technique.

The term “substantially” encompasses absolute conformity with a requirement as well as minor deviation from absolute conformity with the requirement due to manufacturing process variations, assembly, and other factors that may cause a deviation from the ideal. Provided that the deviation is within process tolerances so as to achieve practical conformity and the components described herein are able to function according to the application requirements, the term “substantially” encompasses any of these deviations.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A packaged semiconductor device, comprising:
a die paddle;
a semiconductor die mounted on the die paddle;
a plurality of fused leads extending away from a first side of the die paddle;
a discrete lead that extends away from the first side of the die paddle and is physically detached from the plurality of fused leads;
a first electrical connection between a first terminal of the semiconductor die and the discrete lead;
an encapsulation material that encapsulates the semiconductor die; and
a stabilizer bar connected to a first outer edge side of the discrete lead,
wherein the first outer edge side of the discrete lead is opposite from a second outer edge side of the discrete lead which faces the plurality of fused leads.

2. The packaged semiconductor device of claim 1, wherein the fused leads and the discrete lead extend to a first outer sidewall of the encapsulation material, wherein the stabilizer bar extends to a second outer sidewall of the encapsulation material, and wherein the first and second outer sidewalls of the encapsulation material are angled relative to one another.

3. The packaged semiconductor device of claim 1, wherein a gap that spans a complete length of the discrete lead is provided between the second outer edge side of the discrete lead and the plurality of fused leads.

4. The packaged semiconductor device of claim 1, wherein a thickness of the stabilizer bar is less than a thickness of the discrete lead.

5. The packaged semiconductor device of claim 4, wherein the stabilizer bar comprises an upper surface that is coplanar with an upper surface of the discrete lead and a lower surface that is vertically offset from a lower surface of the discrete lead, and wherein the lower surface of the stabilizer bar is covered by the encapsulation material.

6. The packaged semiconductor device of claim 1, further comprising a second stabilizer bar connected to the first outer edge side of the discrete lead.

7. A lead frame, comprising:
a peripheral structure;
a die paddle comprising a first edge side that faces and is spaced apart from a first edge side of the peripheral structure;
a plurality of fused leads that are each connected to the first edge side of the peripheral structure and are each fused together by a fuse connector at a location that is between the first edge side of the peripheral structure and the die paddle;
a discrete lead that is connected to the first edge side of the peripheral structure, and is separated from the fuse connector; and
a stabilizer bar that is connected between the peripheral structure and an outer edge side of the discrete lead.

8. The lead frame of claim 7, wherein the discrete lead comprises first and second opposite facing outer edge sides that each connect to the first edge side of the peripheral structure at a first location, and wherein the stabilizer bar connects to the first outer edge side of the discrete lead at a second location that is closer to the die paddle than the first location.

9. The lead frame of claim 8, wherein the discrete lead comprises a proximal end that faces the die paddle, and wherein the second location is between the first location and the proximal end of the discrete lead.

10. The lead frame of claim 8, wherein the second outer edge side of the discrete lead faces the plurality of fused leads, and wherein a gap that spans a complete length of the discrete lead is provided between the second outer edge side of the discrete lead and the plurality of fused leads.

11. The lead frame of claim 8, wherein the peripheral structure comprises a second edge side that forms an angled intersection with the first edge side, and wherein the stabilizer bar extends between the second edge side of the peripheral structure and the first outer edge side of the discrete lead.

12. The lead frame of claim 8, wherein the discrete lead is an outermost lead of all leads connected to the first edge side of the peripheral structure, and wherein the stabilizer bar is disposed on a side of the discrete lead that does not face any leads.

13. The lead frame of claim 7, wherein the lead frame further comprises a second stabilizer bar connected between the peripheral ring and the outer edge side of the discrete lead.

14. The lead frame of claim 7, wherein a thickness of the stabilizer bar is less than a thickness of the discrete lead.

15. The lead frame of claim 14, wherein the lead frame comprises opposite facing upper and lower surfaces, wherein the upper surface of the lead frame at the stabilizer bar is substantially coplanar with the upper surface of the lead frame at discrete lead, and wherein the lower surface of the lead frame at the stabilizer bar is vertically offset from the lower surface of the lead frame at discrete lead.

16. A method of manufacturing a lead frame, the method comprising:
providing a planar sheet metal; and
structuring the planar sheet metal to include:
a peripheral structure;
a die paddle connected to the peripheral structure and comprising a first edge side that faces and is spaced apart from a first edge side of the peripheral structure;
a plurality of fused leads that are each connected to the first edge side of the peripheral structure and are each fused together by a fuse connector at a location that is between the first edge side of the peripheral structure and the die paddle;
a discrete lead that is connected to the first edge side of the peripheral structure, and is separated from the fuse connector; and
a stabilizer bar that is connected between the peripheral structure and an outer edge side of the discrete lead.

17. The method of claim 16, wherein the discrete lead comprises first and second opposite facing outer edge sides that each connect to the first edge side of the peripheral structure at a first location, and wherein the stabilizer bar connects to the first outer edge side of the discrete lead at a second location that is closer to the die paddle than the first location.

18. The method of claim 17, wherein the second outer edge side of the discrete lead faces the plurality of fused leads, and wherein a gap that spans a complete length of the discrete lead is provided between the second outer edge side of the discrete lead and the plurality of fused leads.

19. The method of claim 16, wherein the planar sheet metal is structured such that a thickness of the stabilizer bar is less than a thickness of the discrete lead.

20. The method of claim 19, wherein the stabilizer bar is formed by half-etching the planar sheet metal.
